(19) United States
(12) Patent Application Publication
(10) Pub. No.: US 2025/0390153 A1
(43) Pub. Date: Dec. 25, 2025

(54) A MOUNTABLE MOBILE EDGE COMPUTING (MEC) SERVER AND METHOD FOR MOBILE EDGE COMPUTING

(71) Applicant: JIO PLATFORMS LIMITED, Ahmedabad, Gujarat (IN)

(72) Inventors: Narendra KUMAR, South Delhi, Delhi (IN); Aayush BHATNAGAR, Navi Mumbai, Maharashtra (IN); Shakti SINGH, Gurgaon, Haryana (IN); Amrish BANSAL, Navi Mumbai, Maharashtra (IN); Brijesh SHAH, Navi Mumbai, Maharashtra (IN); Bajinder Pal SINGH, Janak Puri, New Delhi (IN); Sumandas D, Mandya, Karnataka (IN); Madan Kishore GARA, Eluru, Andhra Pradesh (IN); Yogesh R. K, Bangalore, Karnataka (IN)

(73) Assignee: JIO PLATFORMS LIMITED, Ahmedabad, Gujarat (IN)

(21) Appl. No.: 18/881,388

(22) PCT Filed: Oct. 17, 2023
(86) PCT No.: PCT/IB2023/060454

§ 371 Date: Jan. 6, 2025

(30) Foreign Application Priority Data
Oct. 31, 2022 (IN) 202221062059

(51) Int. Cl. G06F 1/20; G06F 13/42; H05K 7/20

(52) U.S. Cl. CPC G06F 1/206; G06F 13/4221; G06F 2213/0026; G06F 2213/0032; H05K 7/20409; H05K 7/20809

(57) ABSTRACT

Present disclosure generally relates to computing and wireless communications, particularly, to mobile edge computing (MEC) server and method for MEC. The MEC server includes casing. The casing includes scalable processor comprising external Platform controller Hub (PCH) is configured to perform edge computing of network data associated with telecommunication network. Further, MEC server in casing includes Board Management Controller (BMC) communicatively coupled to PCH is configured to manage functions of motherboard and manage access to remote monitoring function of MEC server. Furthermore, MEC server in casing includes ethernet controllers configured to perform fronthaul connectivity with radio unit associated with telecommunication network, or Backhaul connectivity for optical ethernet associated with telecommunication network. Further, MEC server includes passive thermal cooling unit comprising cooling blocks, fins, and heat sinks, to dissipate heat in MEC server, using passive thermal cooling technique to heat sinks.

### FIELD OF INVENTION

The embodiments of the present disclosure generally relate to a field of computing and wireless communications. More particularly, the present disclosure relates generally to a mountable mobile edge computing (MEC) server and a method for mobile edge computing (MEC).

### BACKGROUND OF THE INVENTION

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Generally, evolution of communication systems poses increasing challenges from an energy consumption perspective. Computational tasks performed by mobile devices may increase as the complexity of such communication systems increases. Additionally, the evolution of communication systems also leads to increased application complexity, which may also cause computational requirements to increase. However, mobile device battery technology has not been able to evolve at the same pace as application complexity. One solution to such issues involved application computation offloading using a Mobile Edge Computing (MEC) technology.

Further, edge servers may be a powerful computing devices deployed at a network edge, where there is a need for a network data computation. The edge servers may be physically close to network systems or applications, that are creating the data being stored on, or used by, the edge server. Further, the edge servers are driving advancements in Artificial Intelligence (AI), a Machine Vision (MV), and deep learning Artificial Neural network (ANN). As a result, there may be multiple researches on moving from traditional data centre environment to edge servers. The edge servers may be able to bring server-like computation to the edge. The edge server may be installed in a National Electrical Manufacturers Association (NEMA) enclosures, which is a custom cabinetry and can be placed in hot, or wet atmosphere such as a desert, a closet, a warehouse, on a desk, a building, a welding studio, traffic signals, outdoor environment, raining environment, and the like. All of these locations are where people have problems with data computation. Further, as compared to Commercial Off-The-Shelf (COTS) server, the edge may need to withstand harsh environment such as rain, dust, moisture, shocks and vibration and with minimum operating cost.

Therefore, there is a need in the art to provide servers and methods that can overcome the shortcomings of the existing prior art, by providing a mobile edge computing (MEC) server and a method for mobile edge computing (MEC).

### OBJECTS OF THE PRESENT DISCLOSURE

Some of the objects of the present disclosure, which at least one embodiment herein satisfy are as listed herein below.

An object of the present disclosure is to provide a system and a method for a mountable mobile edge computing (MEC) server and a method for mobile edge computing (MEC).

Another object of the present disclosure is to provide a mobile edge computing (MEC) server with high computing power and memory closest to the user by adapting an approach of passive thermal cooling.

Another object of the present disclosure is to a mobile edge computing (MEC) server which works in harsh environment such as rain, dust, moisture, shocks and vibrations, and with minimum operating cost.

Another object of the present disclosure is to provide a mobile edge computing (MEC) server which is completely fan less, without any moving parts that increase the system reliability and availability.

Another object of the present disclosure is to provide a mobile edge computing (MEC) server which is easy to deploy on telecommunication tower, street poles or wall inside the buildings.

Another object of the present disclosure adopts a LAN on Mother (LOM) board approach to save over power consumption by the MEC server.

Another object of the present disclosure is to provide a MEC server for providing increased indoor and outdoor performance and enabling a wide range of 5G/6G use cases. This can also significantly enhance user experience in data download rates for all mobile users.

Another object of the present disclosure achieves passive thermal cooling with arrangement of various cooling blocks and heat pipes, without using fans for cooling the MEC server.

### SUMMARY

This section is provided to introduce certain objects and aspects of the present invention in a simplified form that are further described below in the detailed description. This summary is not intended to identify the key features or the scope of the claimed subject matter.

In an aspect, the present disclosure provides a mountable Mobile Edge Computing (MEC) server. The MEC server includes a casing. The casing includes a scalable processor comprising an external Platform controller Hub (PCH) is configured to perform edge computing of network data associated with a telecommunication network. Further, the MEC server in the casing includes a Board Management Controller (BMC) communicatively coupled to the PCH is configured to manage functions of a motherboard and manage access to a remote monitoring function of the MEC server. Furthermore, the MEC server in the casing includes one or more ethernet controllers configured to perform at least one of a fronthaul connectivity with a radio unit associated with the telecommunication network, and a Backhaul connectivity for optical ethernet associated with the telecommunication network. Further, the MEC server in casing includes a passive thermal cooling unit comprising cooling blocks, a plurality of fins, and heat sinks, is configured to dissipate heat generated in the mountable MEC server, using a passive thermal cooling technique to the heat sinks.

In another aspect, the present disclosure provides a method for method for Mobile Edge Computing (MEC). The method includes performing edge computing of network data associated with a telecommunication network, using a scalable processor comprising an external Platform controller Hub (PCH). Further, the method includes managing functions of a motherboard and manage access to a remote monitoring function of a mountable MEC server, using a Board Management Controller (BMC) communicatively coupled to the PCH. Furthermore, the method includes performing at least one of a fronthaul connectivity with a radio unit associated with the telecommunication network, and a Backhaul connectivity for optical ethernet associated with the telecommunication network, using one or more ethernet controllers. Further, the method includes dissipating heat generated in the MEC server, using a passive thermal cooling technique to the heat sinks, using a passive thermal cooling unit comprising cooling blocks, a plurality of fins, and heat sinks.

In another aspect, the present disclosure relates to a non-transitory computer- readable medium comprising a processor to execute processor-executable instructions that cause the processor to perform edge computing of network data associated with a telecommunication network, using a scalable processor comprising an external Platform controller Hub (PCH), manage functions of a motherboard and manage access to a remote monitoring function of a Mobile Edge Computing (MEC) server, using a Board Management Controller (BMC) communicatively coupled to the PCH, perform at least one of a fronthaul connectivity with a radio unit associated with the telecommunication network, and a Backhaul connectivity for optical ethernet associated with the telecommunication network, using one or more ethernet controllers communicatively coupled to the scalable processor, dissipate heat generated in the mountable MEC server, using a passive thermal cooling technique to the heat sinks, using a passive thermal cooling unit comprising cooling blocks, a plurality of fins, and heat sinks that is communicatively coupled to the scalable processor.

### BRIEF DESCRIPTION OF DRAWINGS

The accompanying drawings, which are incorporated herein, and constitute a part of this invention, illustrate exemplary embodiments of the disclosed methods and systems in which like reference numerals refer to the same parts throughout the different drawings. Components in the drawings are not necessarily to scale, emphasis instead being placed upon clearly illustrating the principles of the present invention. Some drawings may indicate the components using block diagrams and may not represent the internal circuitry of each component. It will be appreciated by those skilled in the art that invention of such drawings includes the invention of electrical components, electronic components, or circuitry commonly used to implement such components.

FIG. 1 illustrates an exemplary block diagram representation of a mountable Mobile Edge Computing (MEC) server, in accordance with an embodiment of the present disclosure.

FIGS. 2A-2D illustrate exemplary schematic diagram representations of the mountable Mobile Edge Computing (MEC) server with an enclosure, in accordance with an embodiment of the present disclosure.

FIG. 3 illustrates an exemplary flow diagram representation depicting a method for Mobile Edge Computing (MEC), in accordance with an embodiment of the present disclosure.

FIG. 4 illustrates an exemplary computer system in which or with which embodiments of the present invention can be utilized in accordance with embodiments of the present disclosure.

The foregoing shall be more apparent from the following more detailed description of the invention.

### DETAILED DESCRIPTION OF INVENTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the invention as set forth.

Various embodiments of the present disclosure provide a system and a method for a mountable mobile edge computing (MEC) server and a method for mobile edge computing (MEC). The present disclosure provides a mobile edge computing (MEC) server with high computing power and memory closest to the user by adapting an approach of passive thermal cooling. The present disclosure provides a mobile edge computing (MEC) server which works in harsh environment such as rain, dust, moisture, shocks and vibrations, and with minimum operating cost. The present disclosure provides a mobile edge computing (MEC) server which is completely fan less, without any moving parts that increase the system reliability and availability. The present disclosure provides a mobile edge computing (MEC) server which is easy to deploy on telecommunication tower, street poles or wall inside the buildings. The present disclosure adopts a LAN on Mother (LOM) board approach to save over power consumption by the MEC server. The present disclosure provides a MEC server for providing increased indoor and outdoor performance and enabling a wide range of 5G/6G use cases. This can also significantly enhance user experience in data download rates for all mobile users. The present disclosure achieves passive thermal cooling with arrangement of various cooling blocks and heat pipes, without using fans for cooling the MEC server.

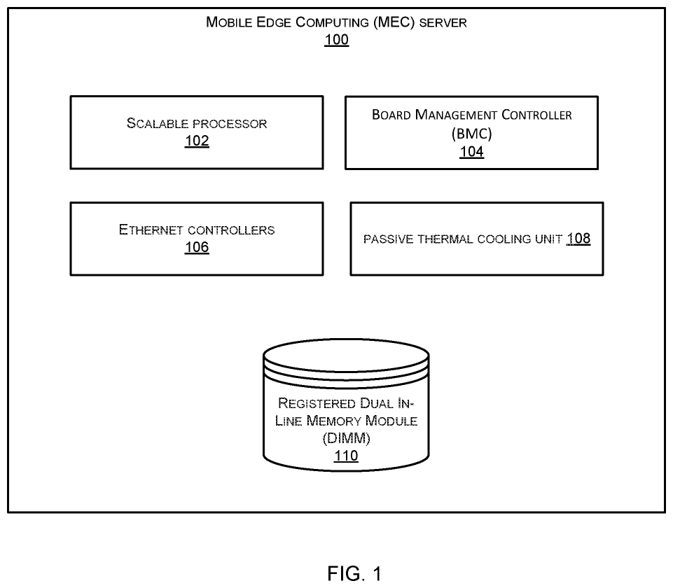

Referring to FIG. 1 illustrating an exemplary block diagram representation of a mountable Mobile Edge Computing (MEC) server (100), in accordance with an embodiment of the present disclosure. As illustrated, the MEC server (100) may include a scalable processor (102), a Board Management Controller (BMC) (104), one or more ethernet controller (106), a passive thermal cooling unit (108), and a Registered Dual In-Line Memory Module (RDIMM) (110) based memory. The MEC server (100) may be a mountable MEC server which may be enclosed in a casing or a sealed casing. The casing may include components of the MEC serve (100). Furthermore, the mobile edge computing (MEC) server (100) may be mounted at a pre-defined height. Hereinafter, the MEC server (100) may be interchangeably referred to as the MEC server (100) or the mountable MEC server (100).

Further, evolution of communication systems poses increasing challenges from an energy consumption perspective. The computational tasks performed by a User Equipment (UE), from an energy consumption point of view, may increase as the complexity of such communication systems increases. For example, when a terminal is connected with multiple Radio Access Technologies (RATs), such as a Wireless-Fidelity (Wi-Fi) access point, a Long Term Evolution (LTE) network, a Fifth Generation (5G) network, a Sixth Generation (6G) network, a New Radio (NR), an Internet of Things (IoT) network, a Narrow band (NB) network, an Open Radio Access Network (ORAN), and the like., an increasing complexity of a physical (PHY) layers and/or Medium Access Control (MAC) layers may require the terminal to perform computationally intensive tasks. This complexity may increase in scenarios where the terminal utilizes Carrier Aggregation (CA) above 5 carriers including a Licensed Assisted Access (LAA), a Licensed Shared Access (LSA), an LTE-Wi-Fi Aggregation (LWA), an LTE-Wi-Fi Radio Level Integration with Internet Protocol Security (IPsec) Tunnelling (LWIP), and the like. Additionally, the evolution of communication systems also leads to increased application complexity, which may also cause computation needs to increase.

Furthermore, an application computation offloading is one of the use cases enabled by the MEC technology. The MEC may be a network architecture that allows cloud computing capabilities and computing services to be performed at the edge of a cellular network/telecommunication network. Further, the MEC provides mechanisms that allow applications to be run and to perform related processing tasks closer to cellular network subscribers (also referred to as “edge users” and the like). In this way, network congestion may be reduced and applications may have better performance. The MEC technology may be designed to be implemented at the cellular base stations, and may enable flexible and rapid deployment of new applications and services for subscribers. Combining elements of information technology and telecommunications networking, the MEC also allows cellular operators to open their Radio Access Network (RAN) to authorized third-parties, such as application developers and content providers.

According to various embodiments, the MEC server (100) may offload computationally demanding tasks by taking into account energy consumption of both computation and communication requirements. Embodiments also exploit multiple Radio Access Technologies (RATs) in order to find opportunities to offload computational tasks (e.g., network functionalities, processing, and offloading coding/encodings, or differentiating traffic between NRT RATs to RT-RATs). Various embodiments herein take into account the communication demand of the applications to be offloaded and the different communication resources available, and exploit the opportunities for joint optimizations when performing application offloading at higher network layers down to Radio Resource Control (RRC) layer, and/or the like. The embodiments herein provide mechanisms, such as RAT interworking, for trading different available RAT resources, depending on required application offloading communication capacity, channel state, backhaul state, and application parameters, and by taking into account energy consumption of computation, communication, and other like parameters/criteria. In embodiments, the RAT interworking may be done according to required application latencies, as well as data and control layer throughputs taking MAC and PHY layer resources into account.

According to various embodiments, a task offloading opportunity may depend on a trade-off between computation (e.g., time and energy, or computational resources) for task execution and energy spent to communicating data (e.g., the input/output of the offloaded task, or network resources). The affordability of this offloading trade-off may depend on the specific application considered. Example use cases of application computation offloading using the MEC server (100) may include, but are not limited to, offloading computationally hungry applications, offloading intermediate data processing applications, offloading moderate data processing applications, and the like. Computation-hungry applications may be applications that are characterized by relatively huge data processing requirements and also by huge data transfer requirements. Examples of computation-hungry applications may include graphics processing/rendering and/or video processing applications, high-speed (low latency) browser applications, artificial/augmented reality applications, low latency cloud-based gaming applications, Three-Dimensional (3D) gaming, and the like. Intermediate data processing applications may be applications that are characterized by relatively large data processing and/or large data transfer requirements that are less stringent than computation-hungry applications. Examples of intermediate data processing applications may include sensor data cleansing (e.g., pre-processing, normalization), video analysis, value-added services such as translation, log analytics, and the like. Moderate data processing applications may be characterized by having smaller data processing and/or data transfer requirements than intermediate data processing applications. Examples of moderate data processing applications may include antivirus applications. At the end, tasks may be conveniently offloaded to a server, with energy benefits for the terminal.

The MEC server (100) may be configured to connect, e.g., communicatively couple, with a Radio Access Network (RAN), which may be, for example, an Evolved Universal Mobile Telecommunications System (UMTS) Terrestrial Radio Access Network (E-UTRAN), a NextGen RAN (NG RAN), an 5G/NR RAN, 6G RAN, Open RAN (ORAN), or some other type of RAN, and the like. In an example, the MEC server (100) may enable communicative coupling with cellular communication protocols, such as a Global System for Mobile Communications (GSM) protocol, a code-division multiple access (CDMA) network protocol, a Push-to-Talk (PTT) protocol, a PTT over Cellular (POC) protocol, a Universal Mobile Telecommunications System (UMTS) protocol, a 3GPP Long Term Evolution (LTE) protocol, a fifth generation (5G) protocol, a New Radio (NR) protocol, a sixth Generation (6G), protocol and the like.

In an embodiment, the MEC (100) may further directly exchange communication data via an interface (not shown). In some implementations the interface may be a Wi-Fi based link or a personal area network (PAN) based link, ZigBee, IPv6 over Low power Wireless Personal Area Networks (6LoWPAN), Wireless HART, MiWi, Thread, etc.; WiFi-direct, Bluetooth/Bluetooth Low Energy (BLE) protocols), and the like. In other implementations, the interface may be an LTE Proximity Services (ProSe) link. The ProSe interface 105 may alternatively be referred to as a Side Link interface, and may comprise one or more logical channels, including but not limited to a Physical Sidelink Control Channel (PSCCH), a Physical Sidelink Shared Channel (PSSCH), a Physical Sidelink Discovery Channel (PSDCH), and a Physical Sidelink Broadcast Channel (PSBCH). In various implementations, the SL interface (not shown) may be used in vehicular applications and communications technologies, which are often referred to as V2X systems.

In an embodiment, the MEC server (100) may execute a scalable processor (102) comprising an external Platform controller Hub (PCH) to perform edge computing of network data associated with a telecommunication network. In an embodiment, the external PCH is configured to expand one or more Input/Outputs (I/Os), and one or more interfaces of the MEC server (100). The external PCH is interfaced on at least one of a Direct Media Interface (DMI) and a Peripheral Component Interconnect express (PCIe) interface with the scalable processor (102). The external PCH provide interface to at least one of a Serial Peripheral Interface (SPI) flash memory for Basic Input/Output System (BIOS), a Peripheral Component Interconnect express (PCIe) for a Solid-State Drive (SSD), and a Serial Advanced Technology Attachment (SATA) for the SSD.

In an embodiment, the MEC server (100) may execute a Board Management Controller (BMC) (104) communicatively coupled to the PCH, to manage functions of a motherboard and manage access to a remote monitoring function of the MEC server (100). The BMC (104) is communicatively coupled to the external PCH via at least one of a Low Pin Count (LPC) bus, a Universal Serial Bus (USB) and a Peripheral Component Interconnect express (PCIe) bus. The motherboard is a Lan on Mother (LOM) board comprising at least 18 layers.

In an embodiment, the MEC server (100) may execute one or more ethernet controllers (106) communicatively coupled to the scalable processor (102), to perform at least one of a fronthaul connectivity with a radio unit associated with the telecommunication network, and a Backhaul connectivity for optical ethernet with the telecommunication network. In an embodiment, the one or more ethernet controllers (106) is further configured to perform at least one of a synchronize real-time clocks and recover real time clocks in the telecommunication network, and perform at least one of an enhanced Common Public Radio Interface (eCPRI) functionalities and an Open Radio Access network (ORAN) functionalities.

In an embodiment, the MEC server (100) may execute a passive thermal cooling unit (108) comprising cooling blocks, a plurality of fins, and heat sinks, that is communicatively coupled to the scalable processor (102), to dissipate heat generated in the mountable MEC server (100), using a passive thermal cooling technique to the heat sinks. The passive thermal cooling technique is a quick transfer of generated heat by one or more pre-fabricated heat pipes. Further, the one or more pre-fabricated heat pipes are placed at a pre-defined intervals.

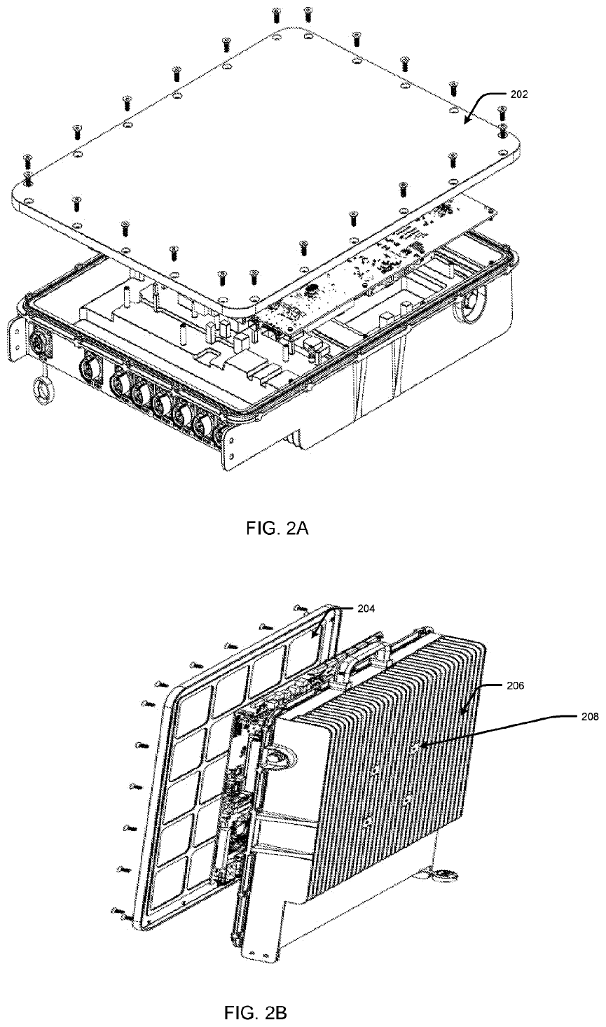

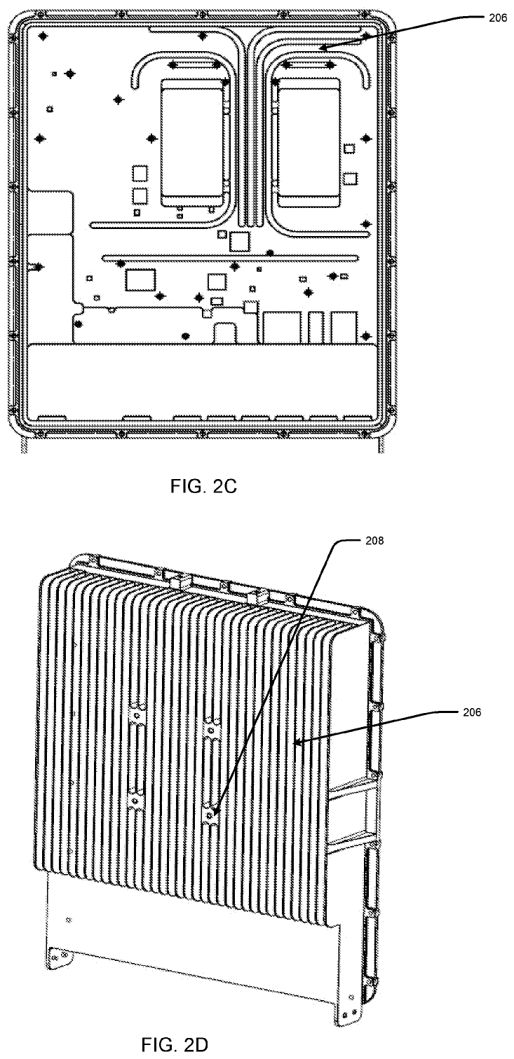

In an embodiment, the mountable MEC server (100) further comprises a Registered Dual In-Line Memory Module (RDIMM) (110) based memory. Further, the passive thermal cooling unit (108) is communicatively coupled to the RDIMM (110) based memory for dissipating the heat generated in the RDIMM (110), by transferring heat using a passive thermal cooling technique to the heat sinks. FIGS. 2A-2D illustrate exemplary schematic diagram representations of the Mobile Edge Computing (MEC) server with an enclosure, in accordance with an embodiment of the present disclosure. FIG. 2A illustrates the casing (202)/sealed casing. Further, FIGS. 2B, 2C and 2D, illustrates the plurality of fins, and the heat sinks (208) for the mountable MEC server (100).

In an embodiment, the MEC server (100) may be a System on Chip (SoC) system but not limited to the like. In another embodiment, an onsite data capture, storage, matching, processing, decision-making, and actuation logic may be coded using Micro-Services Architecture (MSA) but not limited to it. A plurality of microservices may be containerized and may be event-based to support portability.

In an embodiment, the MEC server (100) may be modular and flexible to accommodate any kind of changes in the MEC server (100) as proximate processing may be acquired towards generating adaptive medical queries to determine the disease symptoms of a user. The MEC server (100) configuration details can be modified on the fly.

In an embodiment, the MEC server (100) may be remotely monitored and the data, application, and physical security of the system (108) may be fully ensured. In an embodiment, the data may get collected meticulously and deposited in a cloud-based data lake to be processed to extract actionable insights. Therefore, the aspect of predictive maintenance can be accomplished.

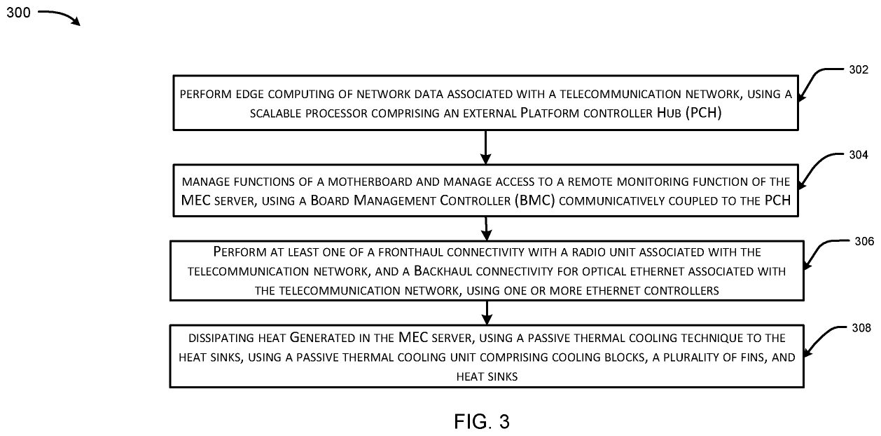

FIG. 3 illustrates an exemplary flow diagram representation depicting a method for Mobile Edge Computing (MEC), in accordance with an embodiment of the present disclosure.

At block (302), the method (300) includes performing, by a MEC server (100), edge computing of network data associated with a telecommunication network, using a scalable processor (102) comprising an external Platform controller Hub (PCH).

At block (304), the method (300) includes managing, by the MEC server (100), functions of a motherboard and manage access to a remote monitoring function of the MEC server (100), using a Board Management Controller (BMC) (104) communicatively coupled to the PCH.

At block (306), the method (300) includes performing, by the MEC server (100), at least one of a fronthaul connectivity with a radio unit associated with the telecommunication network, and a Backhaul connectivity for optical ethernet associated with the telecommunication network, using one or more ethernet controllers (106).

At block (308), the method (300) includes dissipating, by the MEC server (100), heat generated in the MEC server (100), using a passive thermal cooling technique to the heat sinks, using a passive thermal cooling unit (108) comprising cooling blocks, a plurality of fins, and heat sinks.

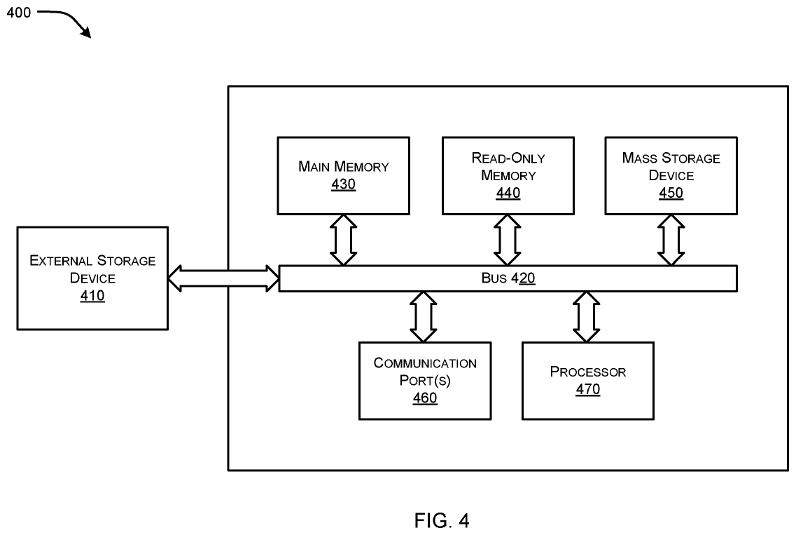

FIG. 4 illustrates an exemplary computer system in which or with which embodiments of the present invention can be utilized in accordance with embodiments of the present disclosure. As shown in FIG. 4, computer system 400 can include an external storage device 410, a bus 420, a main memory 430, a read-only memory 440, a mass storage device 470, a communication port 460, and a processor 470. A person skilled in the art will appreciate that the computer system may include more than one processor and communication ports. Examples of processor 470 include, but are not limited to, an Intel® Itanium® or Itanium 2 processor(s), or AMD® Opteron® or Athlon MP® processor(s), Motorola® lines of processors, FortiSOC™ system on chip processors or other future processors. Processor 470 may include various modules associated with embodiments of the present invention. Communication port 460 can be any of an RS-232 port for use with a modem-based dialup connection, a 10/100 Ethernet port, a Gigabit or 10 Gigabit port using copper or fiber, a serial port, a parallel port, or other existing or future ports. Communication port 460 may be chosen depending on a network, such as a Local Area Network (LAN), Wide Area Network (WAN), or any network to which computer system connects. Memory 430 can be Random Access Memory (RAM), or any other dynamic storage device commonly known in the art. Read-only memory 440 can be any static storage device(s) e.g., but not limited to, a Programmable Read Only Memory (PROM) chips for storing static information e.g., start-up or BIOS instructions for processor 470. Mass storage 470 may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 7102 family) or Hitachi (e.g., the Hitachi Deskstar 7K1000), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

Bus 420 communicatively couples processor(s) 470 with the other memory, storage, and communication blocks. Bus 420 can be, e.g., a Peripheral Component Interconnect (PCI)/PCI Extended (PCI-X) bus, Small Computer System Interface (SCSI), USB, or the like, for connecting expansion cards, drives, and other subsystems as well as other buses, such a front side bus (FSB), which connects processor 470 to a software system.

Optionally, operator and administrative interfaces, e.g., a display, keyboard, joystick, and a cursor control device, may also be coupled to bus 420 to support direct operator interaction with a computer system. Other operator and administrative interfaces can be provided through network connections connected through communication port 460. The external storage device 410 can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

Thus, the present disclosure provides a unique and inventive solution for a diagnostics-as-a-service that may include a medical knowledge that has been curated by the medical experts keeping the Indian demography in mind. This will have great applicability in rendering immediate online diagnostic solutions to the people, even to the remotest areas of the Indian populace for assisting medical students to learn differential diagnosis. The system shall benefit healthcare to less privileged patients by collectively increasing the efficiency of conversation with a virtual doctor by asking appropriate questions which help in providing quick diagnostics and reduce overall costs of disease diagnoses, serve as a reference to medical students assisting them in carrying out a triage with the patient to pose the right questions at right time and diagnose the diseases accurately and collect consistent and adequate information from the patient which potentially leads to an accurate disease diagnosis and various machine learning models to learn on correct information

While considerable emphasis has been placed herein on the preferred embodiments, it will be appreciated that many embodiments can be made and that many changes can be made in the preferred embodiments without departing from the principles of the invention. These and other changes in the preferred embodiments of the invention will be apparent to those skilled in the art from the disclosure herein, whereby it is to be distinctly understood that the foregoing descriptive matter is to be implemented merely as illustrative of the invention and not as a limitation.

### ADVANTAGES OF THE PRESENT DISCLOSURE

The present disclosure provides a mobile edge computing (MEC) server and a method for mobile edge computing (MEC).

The present disclosure provides a mobile edge computing (MEC) server with high computing power and memory closest to the user by adapting an approach of passive thermal cooling.

The present disclosure provides a mobile edge computing (MEC) server which works in harsh environment such as rain, dust, moisture, shocks and vibrations, and with minimum operating cost.

The present disclosure provides a mobile edge computing (MEC) server which is completely fan less, without any moving parts that increase the system reliability and availability.

The present disclosure provides a mobile edge computing (MEC) server which is easy to deploy on telecommunication tower, street poles or wall inside the buildings.

The present disclosure adopts a LAN on Mother (LOM) board approach to save over power consumption by the MEC server.

The present disclosure provides a MEC server for providing increased indoor and outdoor performance and enabling a wide range of 5G/6G use cases. This can also significantly enhance user experience in data download rates for all mobile users.

The present disclosure achieves passive thermal cooling with arrangement of various cooling blocks and heat pipes, without using fans for cooling the MEC server.

### RESERVATION OF RIGHTS

A portion of the disclosure of this patent document contains material which is subject to intellectual property rights such as, but are not limited to, copyright, design, trademark, IC layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

We claim:

1. A Mobile Edge Computing (MEC) server (100) comprising:
a casing, wherein the casing comprising:
a scalable processor (102) comprising an external Platform controller Hub (PCH) is configured to perform edge computing of network data associated with a telecommunication network;
a Board Management Controller (BMC) (104) communicatively coupled to the PCH, is configured to manage functions of a motherboard and manage access to a remote monitoring function of the MEC server (100);
one or more ethernet controllers (106) communicatively coupled to the scalable processor (102), is configured to perform at least one of a fronthaul connectivity with a radio unit associated with the telecommunication network, and a Backhaul connectivity for optical ethernet associated with the telecommunication network; and
a passive thermal cooling unit (108) comprising cooling blocks, a plurality of fins, and heat sinks, that is communicatively coupled to the scalable processor (102), wherein the passive thermal cooling unit (108) is adapted to dissipate heat generated in the MEC server (100), using a passive thermal cooling technique to the heat sinks.

2. The MEC server (100) as claimed in claim 1, wherein the MEC server (100) further comprises a Registered Dual In-Line Memory Module (RDIMM) (110) based memory.

3. The MEC server (100) as claimed in claim 2, wherein the passive thermal cooling unit (108) is communicatively coupled to the RDIMM (110) based memory for dissipating the heat generated in the RDIMM (110), by transferring heat using a passive thermal cooling technique to the heat sinks.

4. The MEC server (100) as claimed in claim 1, wherein the external PCH is configured to expand one or more Input/Outputs (I/Os), and one or more interfaces of the MEC server (100).

5. The MEC server (100) as claimed in claim 1, wherein the external PCH is interfaced on at least one of a Direct Media Interface (DMI) and a Peripheral Component Interconnect express (PCIe) interface with the scalable processor (102).

6. The MEC server (100) as claimed in claim 1, wherein the external PCH provide interface to at least one of a Serial Peripheral Interface (SPI) flash memory for Basic Input/Output System (BIOS), a Peripheral Component Interconnect express (PCIe) for a Solid-State Drive (SSD), and a Serial Advanced Technology Attachment (SATA) for the SSD.

7. The MEC server (100) as claimed in claim 1, wherein the BMC (104) is communicatively coupled to the external PCH via at least one of a Low Pin Count (LPC) bus, a Universal Serial Bus (USB) and a Peripheral Component Interconnect express (PCIe) bus.

8. The MEC server (100) as claimed in claim 1, wherein the motherboard is a Lan on Mother (LOM) board comprising at least 18 layers.

9. The MEC server (100) as claimed in claim 1, wherein the one or more ethernet controllers (106) is further configured to perform at least one of a synchronize real-time clocks and recover real time clocks in the telecommunication network, and perform at least one of an enhanced Common Public Radio Interface (eCPRI) functionalities and an Open Radio Access network (ORAN) functionalities.

10. The MEC server (100) as claimed in claim 1, wherein the passive thermal cooling technique is a quick transfer of generated heat by one or more pre-fabricated heat pipes.

11. The MEC server (100) as claimed in claim 1, wherein the one or more pre-fabricated heat pipes are placed at a pre-defined intervals.

12. The MEC server (100) as claimed in claim 1, wherein the mobile edge computing (MEC) server (100) is mounted at a pre-defined height.

13. A method for Mobile Edge Computing (MEC), the method comprising:
performing, by a MEC server (100), edge computing of network data associated with a telecommunication network, using a scalable processor (102) comprising an external Platform controller Hub (PCH);
managing, by the MEC server (100), functions of a motherboard and manage access to a remote monitoring function of the MEC server (100), using a Board Management Controller (BMC) (104) communicatively coupled to the PCH;
performing, by the MEC server (100), at least one of a fronthaul connectivity with a radio unit associated with the telecommunication network, and a Backhaul connectivity for optical ethernet associated with the telecommunication network, using one or more ethernet controllers (106) communicatively coupled to the scalable processor (102);
dissipating, by the mountable MEC server (100), heat generated in the mountable MEC server (100), using a passive thermal cooling technique to the heat sinks, using a passive thermal cooling unit (108) comprising cooling blocks, a plurality of fins, and heat sinks that is communicatively coupled to the scalable processor (102).

14. The method as claimed in claim 13, wherein the MEC server (100) further comprises a Registered Dual In-Line Memory Module (RDIMM) (110) based memory.

15. The method as claimed in claim 14, wherein the passive thermal cooling unit (108) is communicatively coupled to the RDIMM (110) based memory for dissipating the heat generated in the RDIMM (110), by transferring heat using a passive thermal cooling technique to the heat sinks.

16. The method as claimed in claim 13, wherein the method further comprises expanding, by the MEC server (100), one or more Input/Outputs (I/Os), and one or more interfaces of the MEC server (100) using the external PCH.

17. The method as claimed in claim 13, wherein the external PCH is interfaced on at least one of a Direct Media Interface (DMI) and a Peripheral Component Interconnect express (PCIe) interface with the scalable processor (102).

18. The method as claimed in claim 13, wherein the external PCH provide interface to at least one of a Serial Peripheral Interface (SPI) flash memory for Basic Input/Output System (BIOS), a Peripheral Component Interconnect express (PCIe) for a Solid-State Drive (SSD), and a Serial Advanced Technology Attachment (SATA) for the SSD.

19. The method as claimed in claim 13, wherein the BMC (104) is communicatively coupled to the external PCH via at least one of a Low Pin Count (LPC) bus, a Universal Serial Bus (USB) and a Peripheral Component Interconnect express (PCIe) bus.

20. The method as claimed in claim 13, wherein the motherboard is a Lan on Mother (LOM) board comprising at least 18 layers.

21. A User Equipment (UE) for Mobile Edge Computing (MEC), the UE comprising:
a scalable processor (102) comprising an external Platform controller Hub (PCH) is configured to perform edge computing of network data associated with a telecommunication network;
a Board Management Controller (BMC) (104) communicatively coupled to the PCH, is configured to manage functions of a motherboard and manage access to a remote monitoring function of the MEC server (100);
one or more ethernet controllers (106) communicatively coupled to the scalable processor (102), is configured to perform at least one of a fronthaul connectivity with a radio unit associated with the telecommunication network, and a Backhaul connectivity for optical ethernet associated with the telecommunication network; and
a passive thermal cooling unit (108) comprising cooling blocks, a plurality of fins, and heat sinks, that is communicatively coupled to the scalable processor (102), wherein the passive thermal cooling unit (108) is adapted to dissipate heat generated in the mountable MEC server (100), using a passive thermal cooling technique to the heat sinks.

22. A non-transitory computer-readable medium comprising a processor to execute processor-executable instructions that cause the processor to:
perform edge computing of network data associated with a telecommunication network, using a scalable processor (102) comprising an external Platform controller Hub (PCH);
manage functions of a motherboard and manage access to a remote monitoring function of a Mobile Edge Computing (MEC) server (100), using a Board Management Controller (BMC) (104) communicatively coupled to the PCH;
perform at least one of a fronthaul connectivity with a radio unit associated with the telecommunication network, and a Backhaul connectivity for optical ethernet associated with the telecommunication network, using one or more ethernet controllers (106) communicatively coupled to the scalable processor (102);
dissipate heat generated in the mountable MEC server (100), using a passive thermal cooling technique to the heat sinks, using a passive thermal cooling unit (108) comprising cooling blocks, a plurality of fins, and heat sinks that is communicatively coupled to the scalable processor (102).
